(19) United States
(12) Patent Application Publication
(10) Pub. No.: US 2026/0173483 A1
(43) Pub. Date: Jun. 18, 2026

(54) SELF-ALIGNED BACKSIDE CONTACTS IN A SEMICONDUCTOR DEVICE

(71) Applicant: INTERNATIONAL BUSINESS MACHINES CORPORATION, ARMONK, NY (US)

(72) Inventors: Minhaz Abedin, Delmar, NY (US); Ruilong Xie, Niskayuna, NY (US); Xiaoming Yang, Clifton Park, NY (US); Mahender Kumar, Clifton Park, NY (US); Ravikumar Ramachandran, Pleasantville, NY (US); Kisik Choi, Watervliet, NY (US)

(21) Appl. No.: 18/986,694

(22) Filed: Dec. 18, 2024

(51) Int. Cl. H10D 64/23; H10D 30/00; H10D 30/01; H10D 62/10; H10D 64/01; H10D 64/27

(52) U.S. Cl. CPC H10D 64/258; H10D 30/0198; H10D 30/501; H10D 62/116; H10D 64/017; H10D 64/512

(57) ABSTRACT

A semiconductor device, comprising a source/drain epitaxy. A first dielectric cap is under the source/drain epitaxy on a backside of the semiconductor device. The semiconductor device includes a gate and a second dielectric cap formed under the gate. A spacer separates the first dielectric cap and the source/drain epitaxy from the second dielectric cap and the gate.

### BACKGROUND OF THE INVENTION

The present invention relates to semiconductor memory cells and methods of forming the same. More particularly, the present application relates to form self-aligned backside contacts in a semiconductor device.

Semiconductor devices such as nanosheet field-effect transistors often employ bottom dielectric isolation technology. To do so, a dielectric layer is implemented between the source/drain region epitaxy and the underlying substrate. The direct backside contacts for the source/drain epitaxy may be formed by first growing a placeholder material and then

### SUMMARY

A semiconductor device comprises a source/drain epitaxy. A first dielectric cap is under the source/drain epitaxy on a backside of the semiconductor device. The semiconductor device includes a gate and a second dielectric cap formed under the gate. A spacer separates the first dielectric cap and the source/drain epitaxy from the second dielectric cap and the gate.

A further semiconductor device comprises a source/drain epitaxy, a first gate, and a second gate. The source/drain epitaxy is located between the first and the second gates. A backside source/drain connector formed under the source/drain epitaxy is on a backside of the semiconductor device. Spacers on both sides of the backside source/drain connector separate the backside source/drain connector from first and the second gates.

A method of fabricating a semiconductor device comprises etching a stack of nanosheet layers to form a first gate, a second gate, and a third gate, with a first trench between the first gate and the second gate and a second trench between the second gate and the third gate. The first, second and third gates include SiGe layers and silicon layers. The SiGe layers are etched to form indentations in the first gate, the second gate, and the third gate. A spacer material is formed in the indentations in the first gate, the second gate, and the third gate. A first source/drain epitaxy is formed in the first trench. The spacer material in the indentations in the first and the second gates separate the first source/drain epitaxy from the first and the second gates. A second source/drain epitaxy is formed in the second trench. The spacer material in the indentations in the second and the third gates separate the second source/drain epitaxy from the second and the third gates.

### BRIEF DESCRIPTION OF THE DRAWINGS

FIGS. 1A and 1B illustrate an embodiment of operations to form self-aligned backside contacts for the gate and source/drain epitaxy in a semiconductor device.

FIG. 2 is a top-down diagram illustrating the overall layout of the present semiconductor device and the orientations of the X, Y1 and Y2 cross-sectional views shown in the figures according to an embodiment of the present invention.

FIG. 3 illustrates an embodiment of a nanosheet stack.

FIG. 4 illustrates an embodiment of forming a shallow trench isolation layer between nanosheet stacks.

FIGS. 5A-22A, 5B-22B, and 5C-22C illustrate an embodiment of a progression of the formation of a semiconductor device according to the operations of FIGS. 1A and 1B along X, Y1, and Y2 cross-sectional views.

FIG. 23 illustrates an alternative embodiment of a nanosheet stack.

FIG. 24 illustrates an alternative embodiment of the etching of a cavity in the gates with indentations.

FIG. 25 illustrates an alternative embodiment of forming a dielectric material in the cavities in the gates.

FIG. 26 illustrates an alternative embodiment of forming the backside gate and source/drain contacts with dielectric material in the indentations in the spacers.

### DETAILED DESCRIPTION

Described embodiments provide improved techniques for forming backside contacts for the gate and source/drain epitaxy without the use of placeholders. Placeholders have disadvantages as the size of the semiconductor devices scales down. Placeholders have the disadvantages of complexity to grow a placeholder material, usually Si-Ge, dependent placeholder growth, non-uniform depth, and the etch to remove the placeholder can cause a short.

Described embodiments provide an improved method for forming the backside contacts of a semiconductor device by using a gate spacer defined self-aligned backside contact. Further, different dielectric cap materials may be used to file the regions for the backside gate and source/drain contacts to allow for selective etching of the dielectric cap materials to form the backside contacts for the source/drain epitaxy and the gate to avoid shorts.

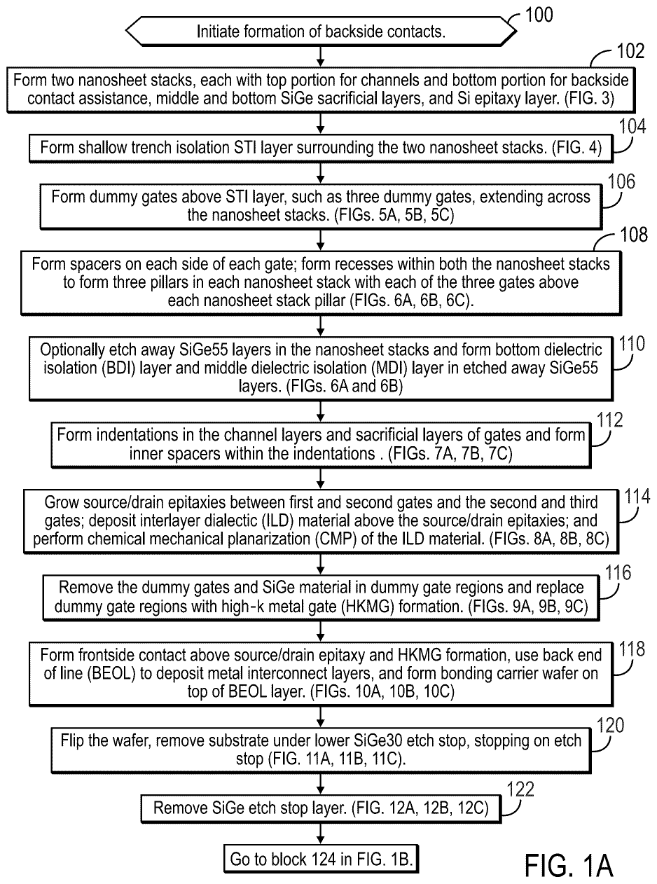

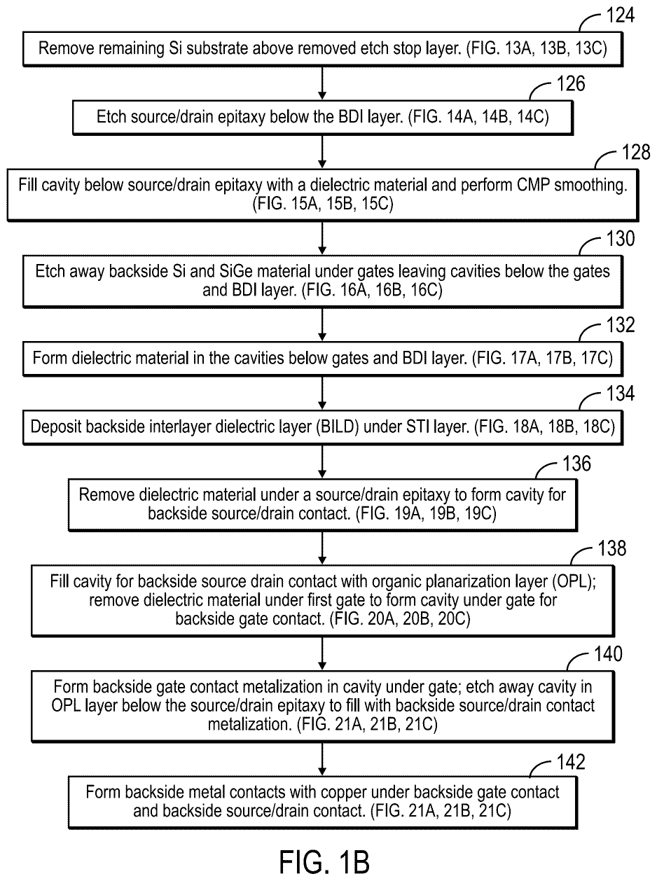

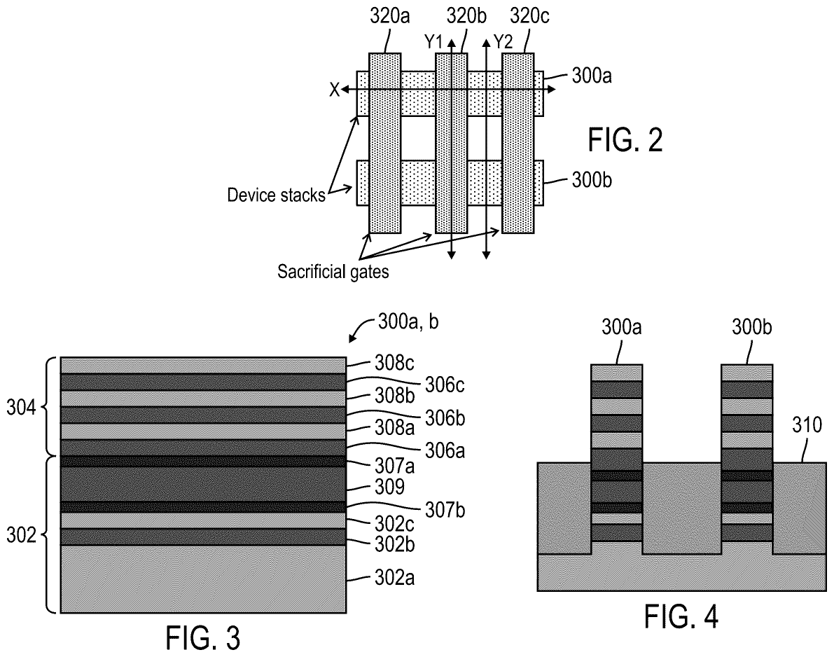

An exemplary methodology for fabricating a semiconductor device in accordance with the present techniques is now described by way of reference to FIGS. 1A and 1B. showing the process for fabricating the semiconductor and FIGS. 2-4, 5A-22A, 5B-22B, and 5C-22C which illustrate the progression of the formation of the backside contacts for the semiconductor device

FIG. 2 is a top-down diagram illustrating an overall layout of the present semiconductor device design. As shown in FIG. 2, the present semiconductor device includes at least one active area having, for example, device stacks 300a, 300b of sacrificial/active layers on a frontside of a wafer (see below), and sacrificial gates 320a, 320b, 320c disposed over, and oriented orthogonal to, the active area(s).

The term “sacrificial,” as used herein, generally refers to any material or structure that is used in one part of the process, and then later removed, in whole or in part, during fabrication of the semiconductor device. Thus, as is apparent from FIG. 2, a gate-last approach will be employed in the present example. With a gate-last approach, sacrificial gates are used as a placeholder during formation of the source/drain regions. The sacrificial gates are removed later on in the process, and replaced with the final gates of the device (also referred to herein as “replacement gates”). When the replacement gates are metal gates, they may also be referred to herein as “replacement metal gates.” Advantageously, use of a gate-last process avoids exposing the replacement gate materials such as high-κ dielectrics to potentially damaging conditions such as the high temperatures experienced during source/drain region formation.

FIG. 2 further illustrates the orientations of the cross-sectional views that will be illustrated in the following figures. For instance, as shown in FIG. 2, the X cross-sectional views shown in the following figures depict cuts through one of the active areas, across each of the sacrificial gates. The Y1 cross-sectional views depict cuts, perpendicular to the X cross-sectional views, through one of the sacrificial gates. The Y2 cross-sectional views depict cuts, also perpendicular to the X cross-sectional views, but in between two of the sacrificial gates.

With respect to FIG. 1A, upon initiating (at block 100) formation of a semiconductor device with backside contacts, two nanosheet stacks are formed (at block 102). Each of the stacks 300a, 300b include a top portion for channels, bottom portion for backside contact assistance, middle and bottom SiGe sacrificial layers, and Si epitaxy layer. FIG. 3 illustrates an embodiment of the each of the nanosheet stacks 300a, 300b formed at step 102.

As shown in FIG. 3 (which appears the same for X, Y1 and Y2 cross-sectional views), the process begins with the formation of a sacrificial/active layer stack 304 on a first side (A), i.e., the frontside, of a wafer 302. According to an exemplary embodiment, wafer 302 includes a substrate 302a, an etch stop layer 302b, such as comprised of SiGe30, disposed directly on the substrate 302a, and a semiconductor layer 302c disposed directly on the etch stop layer 302c.

In one exemplary embodiment, wafer 302 a is a bulk semiconductor wafer, such as a bulk silicon (Si) wafer, and etch stop layer 302b is formed from silicon germanium (SiGe30) that is epitaxially grown from the (Si) substrate 302a. In turn, semiconductor layer 302c (e.g., Si) can be epitaxially grown from the etch stop layer 302b. In that case, the etch stop layer 302b is preferably formed from a low germanium (Ge) content SiGe. For instance, in one exemplary embodiment, low Ge content SiGe is SiGe having from about 15% Ge to about 35% Ge. For example, in one non-limiting embodiment, etch stop layer 302b is formed from SiGe30 (which is SiGe having a Ge content of about 30%).

Sacrificial/active layer stack 304 includes alternating sacrificial and active layers oriented horizontally one on top of another on wafer 302 (in particular, on semiconductor layer 302c of wafer 302). In one exemplary embodiment, the sacrificial and active layers are nanosheets. The term “nanosheet” as used herein, generally refers to a sheet or a layer having nanoscale dimensions. Further, the term “nanosheet” is meant to encompass other nanoscale structures such as nanowires. For instance, the term “nanosheet” can refer to a nanowire with a larger width, and/or the term “nanowire” can refer to a nanosheet with a smaller width, and vice versa.

Specifically, as shown in FIG. 3, the sacrificial/active layer stack 304 includes alternating layers of sacrificial layers 306a, b, c and 307a, b, and active layers 308a,b,c, etc. deposited on the wafer 302. The present techniques involve the formation of at least one field-effect transistor of the semiconductor device on the first side (A), i.e., frontside, of the wafer 302 which, as will be described in detail below, includes removal of the sacrificial layers 306a,b,c, etc. later on in the process to permit the formation of a gate-all-around configuration for the semiconductor device. By contrast, active layers 308a,b,c, etc. will remain in place and serve as channels of the field-effect transistor(s). It is notable that the number of sacrificial layers 306a,b,c, etc. and active layers 308a, b, c, etc. shown in the figures is provided merely as an example to illustrate the present techniques. For instance, embodiments are contemplated herein where more or fewer sacrificial layers 306a,b,c, etc. and/or more or fewer active layers 308a,b,c, etc. are present than shown. According to an exemplary embodiment, each of the sacrificial layers 306a,b,c, 307a, 307b and each of the active layers 308a,b,c, etc. is deposited/formed on semiconductor layer 302c of wafer 302 using an epitaxial growth process. According to an exemplary embodiment, each of the sacrificial layers 306a,b,c, etc. and each of the active layers 308a,b,c, etc.

The materials employed for the sacrificial layers 306a,b,c, etc. and active layers 308a, b, c, etc. are such that the sacrificial layers 306a,b,c, etc. can be removed selective to the active layers 308a, b, c, etc. during fabrication. For instance, according to an exemplary embodiment, the sacrificial layers 306a,b,c, 307a, 307b are each formed from SiGe, while the active layers 308a,b,c, etc. are each formed from Si. Etchants such as wet hot SC1, vapor phase hydrogen chloride (HCl), vapor phase chlorine trifluoride (ClF3) and other reactive clean processes (RCP) are selective for etching of SiGe versus Si. In that case, the sacrificial layers 306a,b,c, etc. are preferably formed from a low Ge content SiGe, i.e., SiGe having from about 15% Ge to about 35% Ge. For example, in one non-limiting embodiment, the sacrificial layers 206a, b, c, etc. are formed from SiGe30. This is, however, only one exemplary combination of sacrificial/active material that may be employed in accordance with the present techniques. For instance, by way of example only, the opposite configuration can instead be implemented where the sacrificial layers 306a,b,c, etc. are each formed from Si, and the active layers 308a,b,c, etc. are each formed from (low Ge content) SiGe. The sacrificial layers 307a, 307b may be formed of SiGe 55.

Standard lithography and etching techniques can be employed to pattern the sacrificial/active layer stack 304 into the individual device stacks 300a, b. With standard lithography and etching techniques, a lithographic stack (not shown), e.g., photoresist/anti-reflective coating/organic planarizing layer, is used to pattern a hardmask (not shown) with the footprint and location of the device stacks 300a, 300b. Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

At block 104 in FIG. 1A, a shallow trench isolation (STI) layer is formed surrounding the nanosheet stacks. FIG. 4 illustrates an embodiment of an example of the STI layer 310 formed on the nanosheet stacks 300a, 300b, taken along the Y1 axis.

To form the shallow trench isolation regions 310, a dielectric such as an oxide (which may also be generally referred to herein as a ‘shallow trench isolation oxide’) is deposited into, and filling, the trenches between the device stacks 300a, 300b, followed by planarization and recess. Suitable shallow trench isolation oxides include, but are not limited to, oxide low-κ materials such as silicon oxide (SiO₂) and/or oxide ultralow-κ interlayer dielectric (ULK-ILD) materials, e.g., having a dielectric constant κ of less than 3.5. Suitable ultralow-κ dielectric materials include, but are not limited to, porous organosilicate glass (pSiCOH). A process such as chemical vapor deposition (CVD), atomic layer deposition (ALD), or physical vapor deposition (PVD) can be employed to deposit the shallow trench isolation oxide, after which the shallow trench isolation oxide can be planarized using a process such as chemical mechanical polishing. After that, the shallow trench isolation oxide is recessed using a dry or wet etch process to form the shallow trench isolation regions 310 at a base of the layers 302a, b, etc.

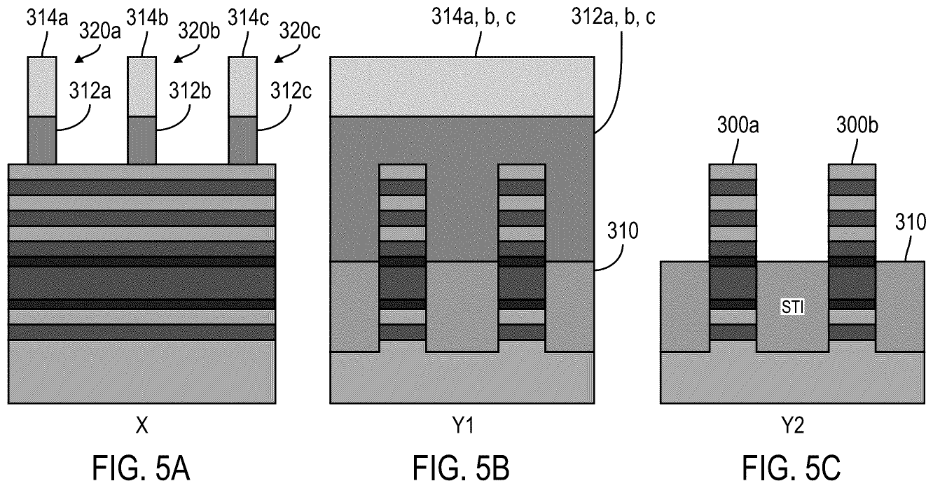

At block 106 in FIG. 1A, dummy gates are formed above the STI layer. Three dummy gates are formed extending across the nanosheet stacks. FIGS. 5A, 5B, 5C, taken along the X, Y1, and Y2 axes, respectively, illustrate an embodiment of the dummy gates 312a, 312b, 312c and high metal gates 314a, 314b, 314c. The dummy gates and high metal gates form the gates 320a, 320b, 320c.

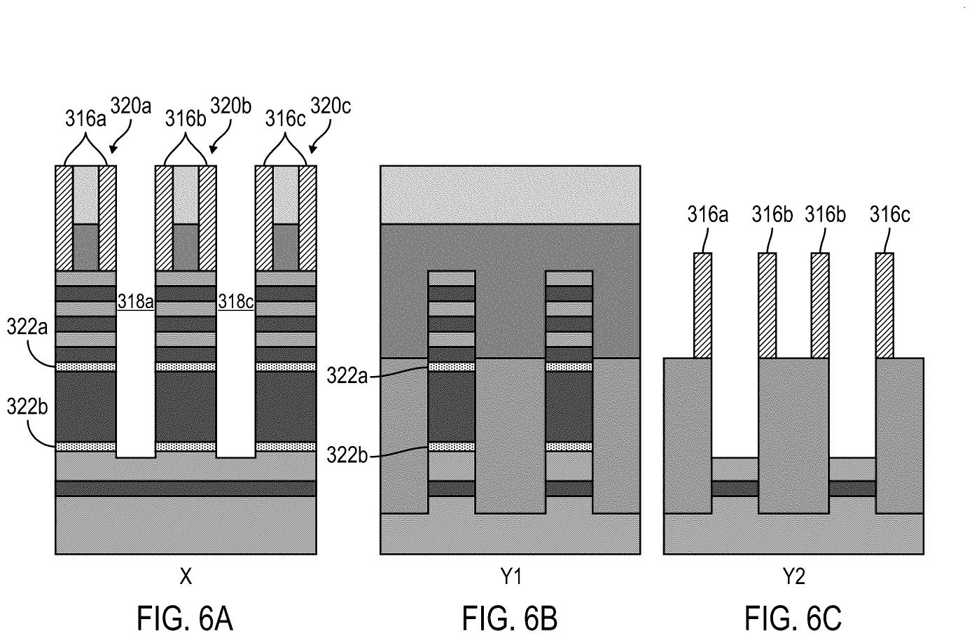

At block 108 in FIG. 1A, dielectric spacers are formed on sides of each gate. Recesses are also formed within both the nanosheet stacks to form the gates in each nanosheet stack. FIGS. 6A, 6B, 6C, taken along the X, Y1, and Y2 axes, respectively, illustrate an embodiment of the spacers 316a, 316b, 316c formed on the side of the gates and trenches 318a, 318b formed in the nanosheet stacks 300a, 300 to separate the three gates 320a, 320b, 320c in the nanosheet stacks. Certain embodiments may not have the structures 316a, 316b, 316c over the STI layer. Suitable dielectric spacer materials include, but are not limited to, SiOx, silicon carbide (SiC), silicon oxycarbide (SiCO), SiN, silicoboron carbonitride (SiBCN) and/or silicon oxycarbonitride (SiOCN), which can be deposited using a process such as CVD, ALD or PVD.

At block 110 in FIG. 1A, SiGe55 layers in the nanosheet stacks may be etched away. A bottom dielectric isolation (BDI) layer and middle dielectric isolation (MDI) layer may be formed in the etched away SiGe55 layers. FIGS. 6A and 6B show the middle dielectric layer 322a formed in etched away SiGe55 layer 307a (FIG. 3) and lower dielectric layer 322b formed in etched away SiGe55 layer 307b (FIG. 3). In certain embodiments, there may be no middle and/or lower dielectric layer. In such case, one or both of the isolations and the starting stack shown in FIG. 3 will change accordingly. e.g. for embodiment with BDI, starting stack will only contain 307b (no 307a).

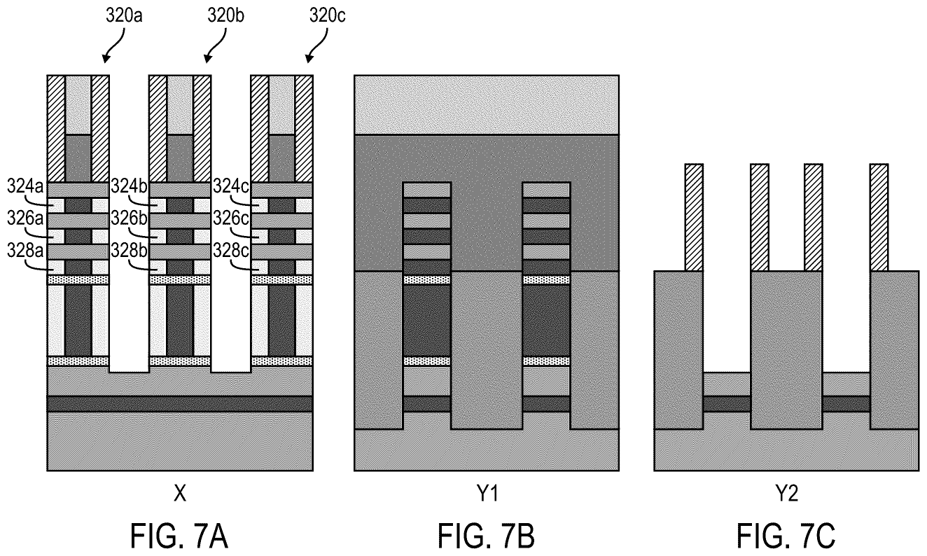

At block 112 in FIG. 1A, indentations are formed in the sacrificial layers of the gates. Inner spacers are formed in the indentations. FIGS. 7A, 7B, 7C, taken along the X, Y1, and Y2 axes, respectively, illustrate the formation of spacers 324a, 324b, 324c, 326a, 326b, 326c, 328a, 328b, and 382c in the formed indentations for the gates 320a, 320b, 320c.

To form the inner spacers 324a, 324b, 324c, 326a, 326b, 326c, 328a, 328b, and 382c, a selective lateral etch is performed to first recess the sacrificial layers 306a,b,c (FIG. 3). This etched recess forms pockets along the sidewalls of the first/shallow trenches between the gates 320a, 320b, 320c. These recessed are filled with a dielectric spacer material to form the spacers within the pockets. The spacers will serve to offset the replacement gates from the source/drain regions (see below). As provided above, the sacrificial layers 306a,b,c, etc. can be formed from SiGe. In that case, a SiGe-selective non-directional (isotropic) etching process can be used for the recess etch. Suitable dielectric spacer materials for spacers include, but are not limited to, silicon nitride (SiN), SiOx, SiC and/or SiCO. A process such as CVD, ALD or PVD can be employed to deposit the dielectric spacer material into the pockets, after which excess spacer material can be removed using an isotropic etching process such as reactive ion etching.

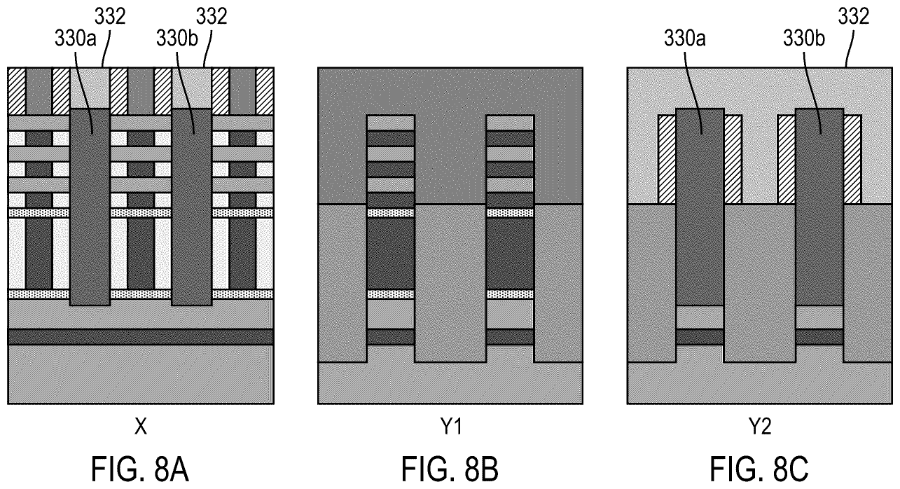

At block 114 in FIG. 1A, source/drain epitaxies are grown between the first and second gates and, separately, the second and third gates. An interlayer dialectic (ILD) material is deposited above the STI layers for each gate. A chemical mechanical planarization (CMP) of the ILD material is performed. FIGS. 8A, 8B, 8C, taken along the X, Y1, and Y2 axes, respectively, illustrate the formation of the source/drain epitaxies 330a, 330b. The ILD 332 is formed above the source/drain epitaxies 330a, 330b and chemical mechanical planarization (CMP) is performed to planarize the ILD material 332.

Suitable interlayer dielectric 332 materials include, but are not limited to, silicon nitride (SiN), SiOC and/or oxide low-κ materials such as SiOx and/or oxide ULK-ILD materials such as pSiCOH, which can be deposited onto the semiconductor device structure using a process such as CVD, ALD or PVD. According to an exemplary embodiment, the interlayer dielectric 332 is a different dielectric material from the shallow trench isolation regions 310 (e.g., interlayer dielectric 332 can be SiN, and the shallow trench isolation regions 310 can be SiOx).

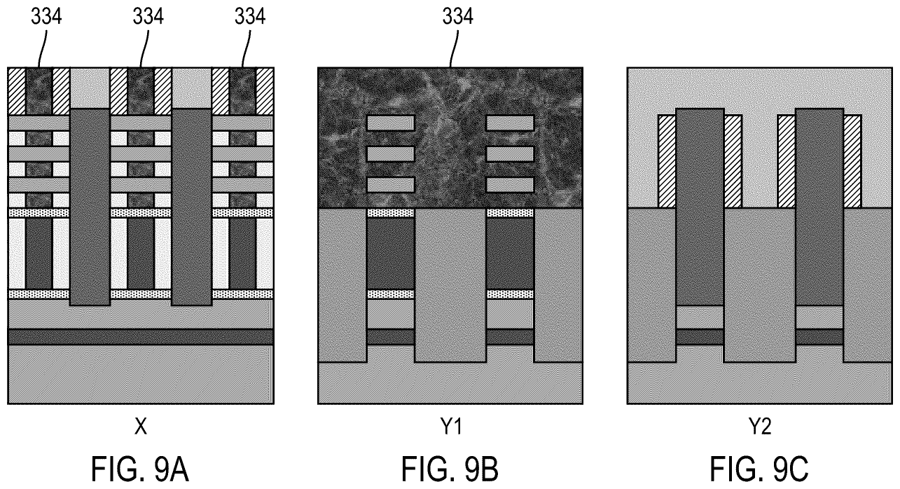

At block 116 in FIG. 1A, the dummy gates and SiGe material in dummy gate regions are removed. The dummy gate regions are replaced with a high-k metal gate (HKMG) formation. FIGS. 9A, 9B, 9C, taken along the X, Y1, and Y2 axes, respectively, illustrate the removal of the dummy gates 312a, 312b, 312c (FIGS. 5A, 5B) and replacement with a metal gate 334.

In one embodiment, formation of the replacement gates 334 begins with the deposition of a (conformal) gate dielectric onto/surrounding each of the active layers 308a,b,c, etc. The gate dielectric may comprise a high-κ material. The term “high-κ,” as used herein, refers to a material having a relative dielectric constant κ which is much higher than that of silicon dioxide (e.g., a dielectric constant κ=25 for hafnium oxide (HfO2) rather than 4 for SiO2). Suitable high-κ gate dielectrics include, but are not limited to, hafnium oxide (HfO2) and/or lanthanum oxide (La2O3). A process such as CVD, ALD or PVD can be employed to deposit the gate dielectric. A reliability anneal can be performed following deposition of the gate dielectric. In one exemplary embodiment, the reliability anneal is performed at a temperature of from about 500° C. to about 1200° C. and ranges therebetween, for a duration of from about 1 nanosecond to about 30 seconds and ranges therebetween. Preferably, the reliability anneal is performed in the presence of an inert gas such as, but not limited to, nitrogen.

At least one workfunction-setting metal 334 is then deposited over the gate dielectric. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). Suitable p-type workfunction-setting metals include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n-and p-type workfunction-setting metals given above. A process such as CVD, ALD or PVD can be employed to deposit the workfunction-setting metal(s) 334, after which the metal overburden can be removed using a process such as chemical mechanical polishing.

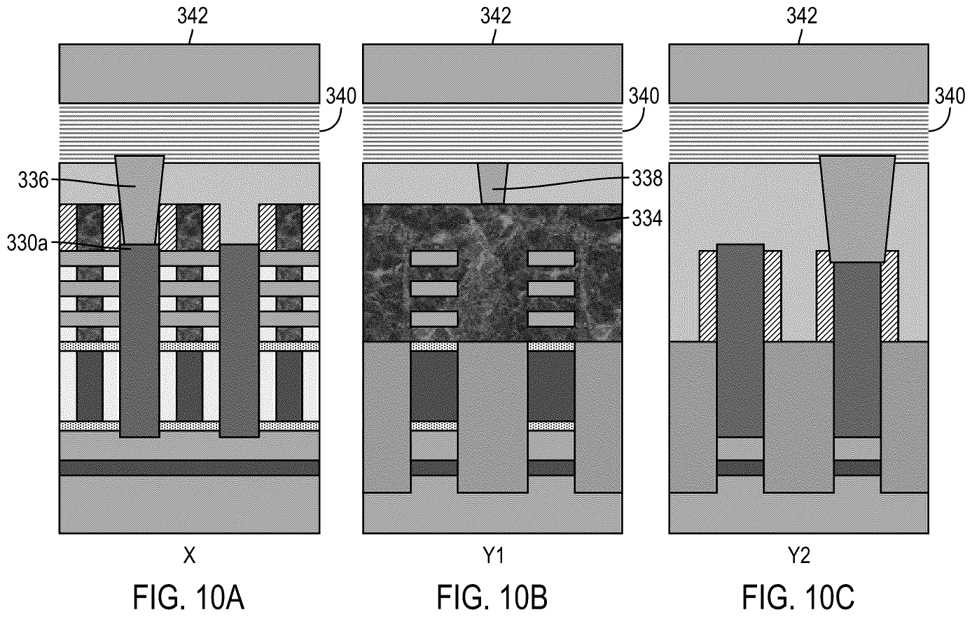

At block 118 in FIG. 1A, frontside contacts are formed above the source/drain epitaxy and HKMG formation. A back end of line (BEOL) is used to deposit metal interconnect layers. A bonding carrier wafer is formed on top of the BEOL layer. FIGS. 10A, 10B, 10C, taken along the X, Y1, and Y2 axes, respectively, illustrate the source/drain contact 336 and gate contact 338. These figures further show the formed BEOL layer 340 and the bonding carrier wafer 342 formed above the BEOL layer 340.

The contacts 336, 338 may be formed through metallization. The metallization can include first depositing a silicide liner, depositing a metal adhesion layer onto the silicide liner, and then depositing a fill metal onto the metal adhesion layer. Suitable silicide liner materials include, but are not limited to, titanium (Ti), nickel (Ni) and/or nickel platinum (NiPt), which can be deposited using a process such as CVD, ALD or PVD. Suitable metal adhesion layer materials include, but are not limited to, TiN and/or TaN, which can be deposited onto the silicide liner using a process such as CVD, ALD or PVD. Suitable fill metals include, but are not limited to, W, Co, Ru and/or Al, which can be deposited onto the metal adhesion layer using a process such as CVD, ALD, PVD, sputtering, plating, evaporation, ion beam deposition, electron beam deposition, laser assisted deposition, chemical solution deposition, etc.

Back end of line interconnect layer (BEOL) 340 generally includes interconnect structures commonly formed in the back end of line during semiconductor device fabrication. Namely, in the back end of line, individual devices such as transistors are interconnected through a series of metal layers. The carrier wafer 342 is then bonded over the back end of line layer (BEOL) 340. Suitable carrier wafers include, but are not limited to, silicon, silicon carbide and/or glass wafers.

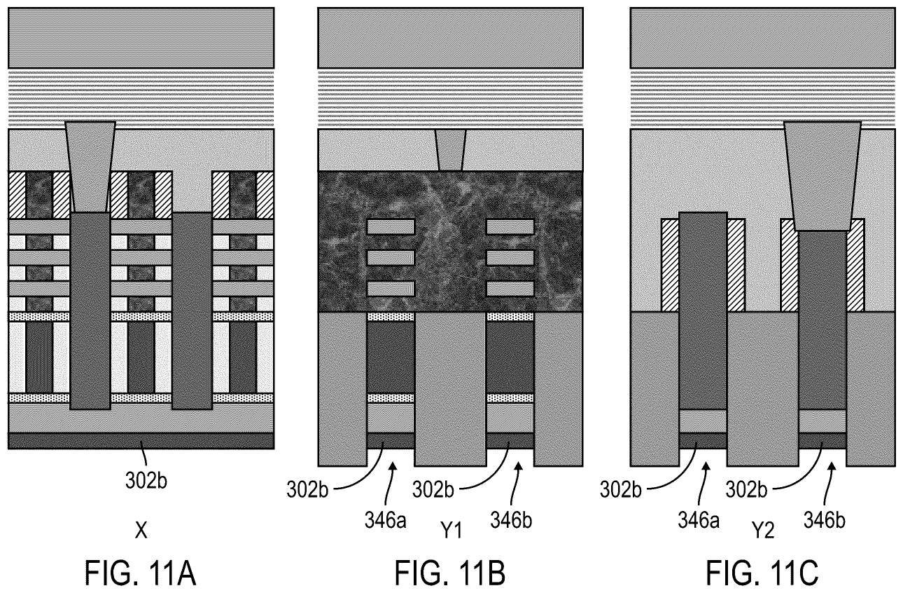

At block 120 in FIG. 1A, the wafer is flipped and the substrate under the lower SiGe30 etch stop is removed, stopping on the etch stop layer. FIGS. 11A, 11B, 11C, taken along the X, Y1, and Y2 axes, respectively, show the removal of the substrate 302a (FIG. 3) using an etch, stopping at the SiGe30 layer 302b (FIG. 3), leaving recesses 346a, 346b below the SiGe30 layer 302b, as shown in FIGS. 11B, 11C.

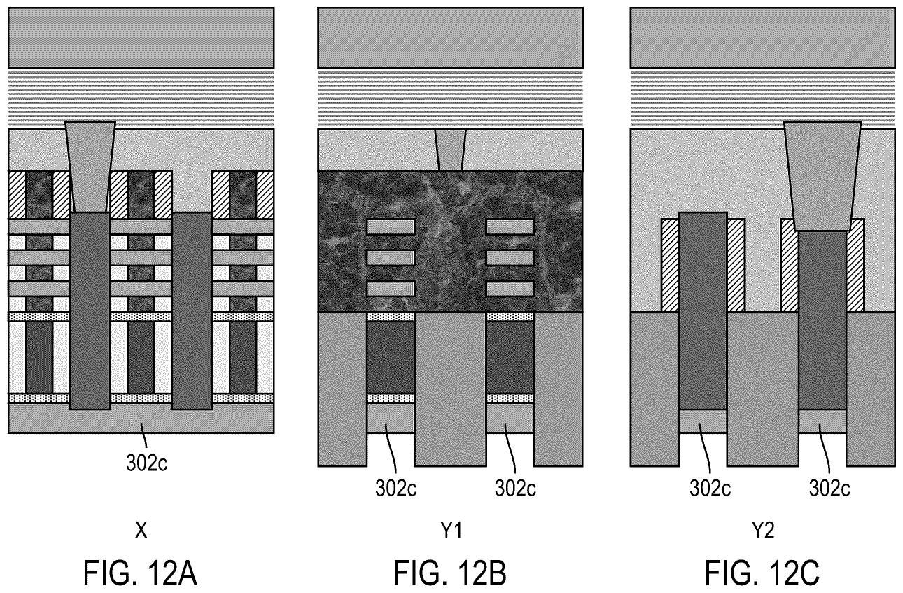

At block 122 in FIG. 1A, the SiGe30 etch stop layer is removed. FIGS. 12A, 12B, 12C, taken along the X, Y1, and Y2 axes, respectively, show the removal of the SiGe30 etch stop layer 302b (FIG. 3), leaving the silicon substrate or semiconductor layer 302c. The etch stop layer 302b can be removed using a SiGe or oxide-selective etch.

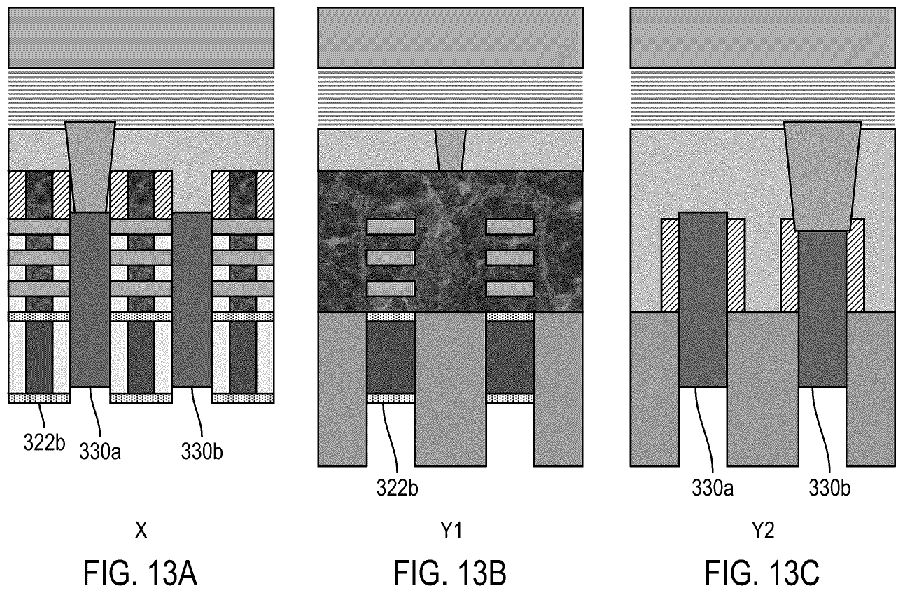

At block 124 in FIG. 1B, the remaining Si substrate layer, above the removed etch stop layer, is removed. FIGS. 13A, 13B, 13C, taken along the X, Y1, and Y2 axes, show the removal of the silicon substrate layer 302c, leaving the bottom dielectric layer 322b and source/drain epitaxies 330a, 330b. The substrate layer 302c can be removed relative to the source/drain epitaxies 330a, 330b, replacement gates, and shallow trench isolation regions using a Si-selective etch.

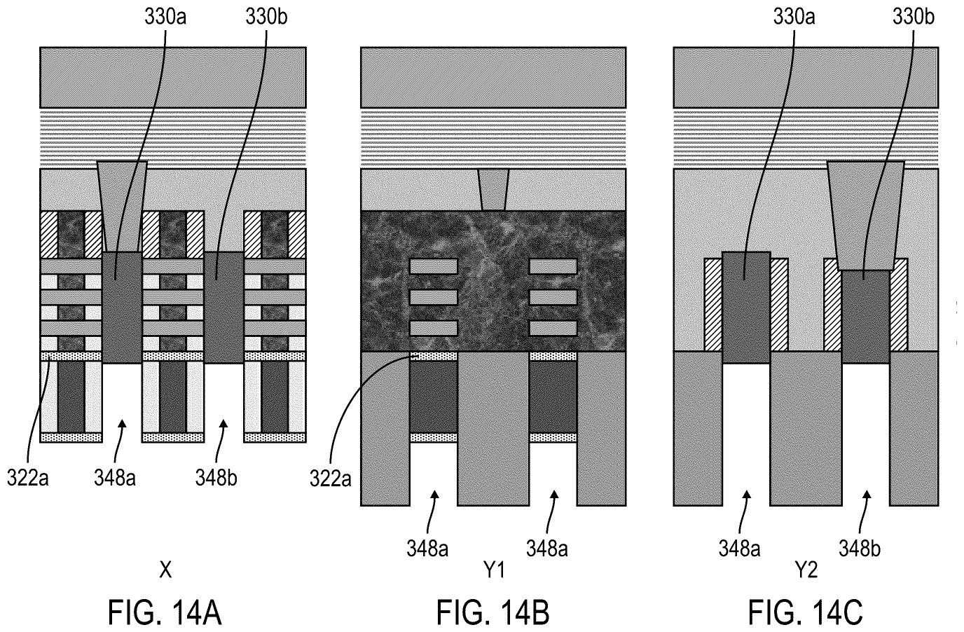

At block 126 in FIG. 1B, the source drain epitaxy 330a, 330b is removed below the middle dielectric layer 322a. FIGS. 14A, 14B, 14C, taken along the X, Y1, and Y2 axes, respectively, show the removal by etching of the source/drain epitaxy below the middle dielectric layer 322a, leaving open cavities 348a, 348b below the remaining source/drain epitaxy 330a, 330b.

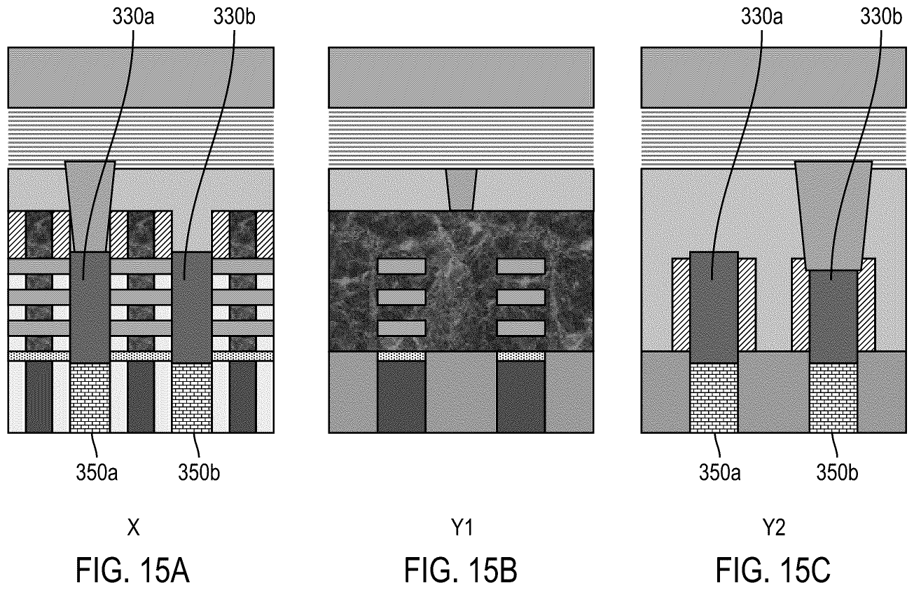

At block 128 in FIG. 1B, the cavities below the source/drain epitaxy are filled with a dielectric material and CMP smoothing is performed on the dielectric material. FIGS. 15A, 15B, 15C, taken along the X, Y1, and Y2 axes, show the dielectric material 350a, 350b formed below the source/drain epitaxies 330a, 330b.

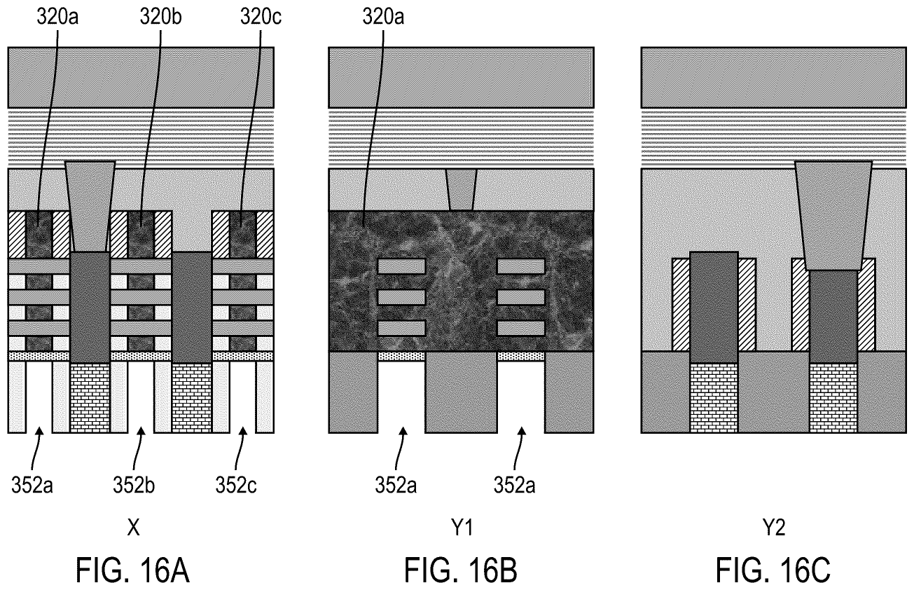

At block 130 in FIG. 1B, the backside Si and SiGe material is etched away under the gates leaving cavities below the gates and BDI layer. FIGS. 16A, 16B, 16C, taken along the X, Y1, and Y2 axes, show the cavities 352a, 352b, 352c formed by removing through etching the SiGe layer 307b (FIG. 3). FIG. 16B shows the cavity 352a formed under one gate 320a.

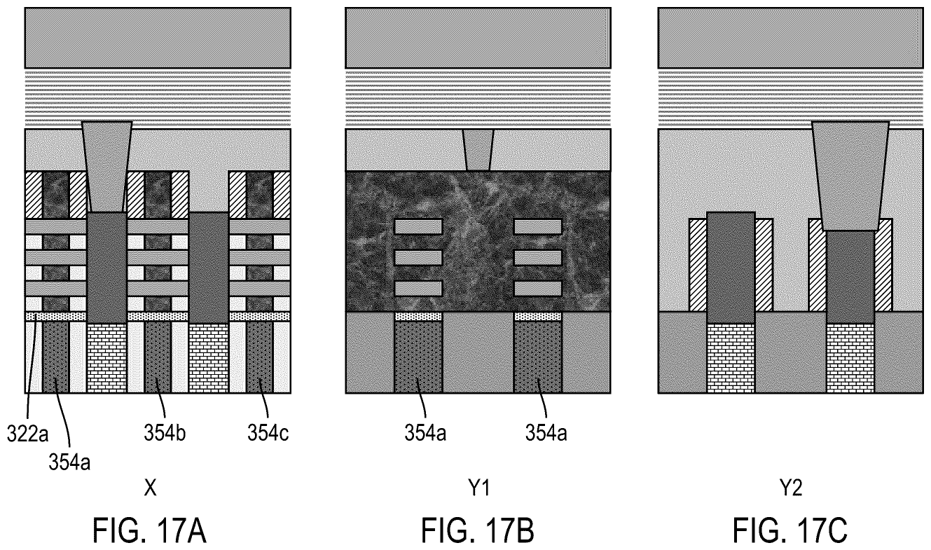

At block 132 in FIG. 1B, a dielectric material is formed in the cavities below the gates and BDI layer. FIGS. 17A, 17B, 17C, taken along the X, Y1, and Y2 axes, shows an embodiment of the dielectric material 354a, 354b, 354 in the cavities 352a, 352b, 352 (FIG. 16A) below the MDI layer 322a. In certain embodiments, the dielectric material 354a, 354b, 354c below the gates may comprise a different dielectric material than the dielectric material 350a, 350b below the source/drain epitaxies 330a, 330b. In one embodiment, the dielectric material 354a, 354b, 354c below the gates may comprise silicon nitride (SiN) and the dielectric material 350a, 350b below the source drain epitaxies may comprise silicon oxide (SiO₂).

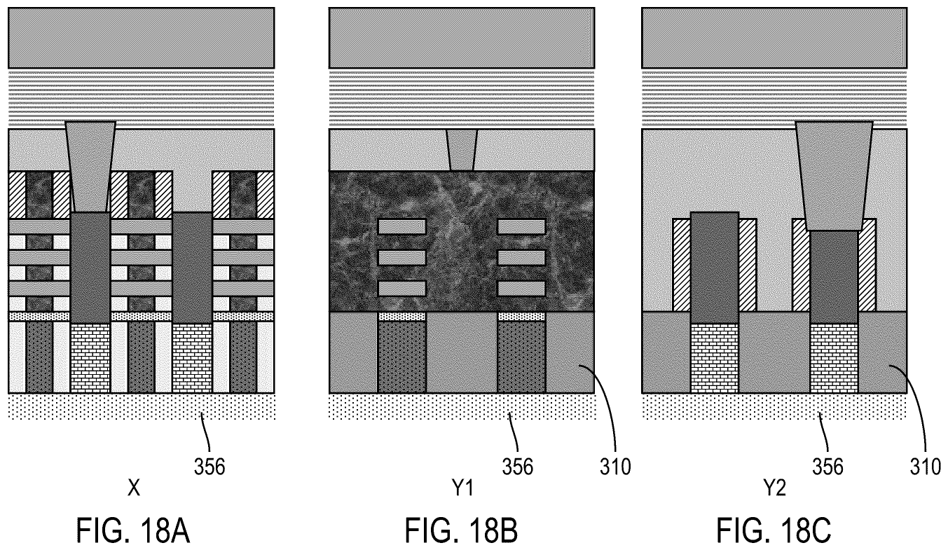

At block 134 in FIG. 1B, a backside interlayer dielectric (BILD) layer is deposited under the STI layer. FIGS. 18A, 18B, 18C, taken along the X, Y1, and Y2 axes, shows an embodiment of the BILD layer 356 deposited under the STI layer 310.

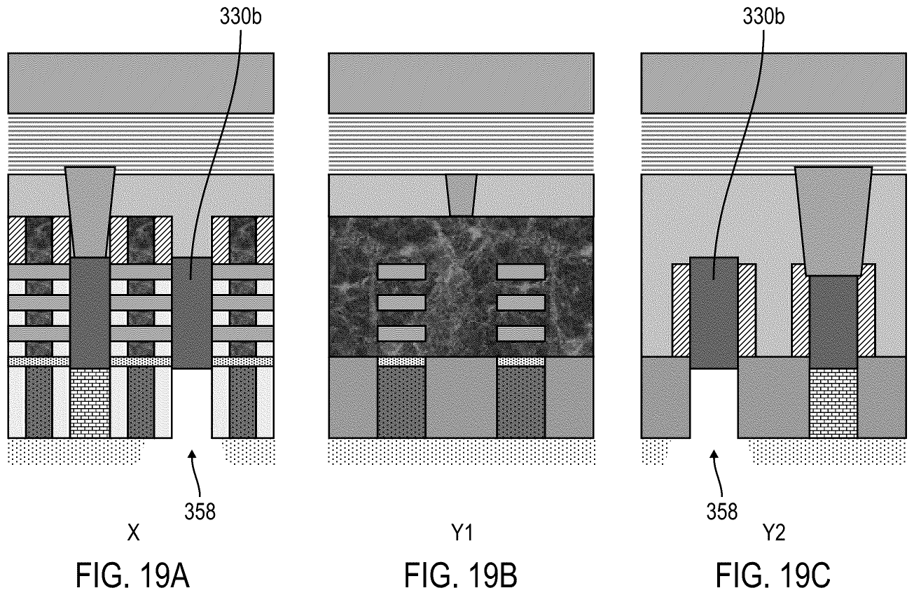

At block 136 in FIG. 1B, the dielectric material under a source/drain epitaxy is etched away to form a cavity for a backside source/drain contact. FIGS. 19A, 19B, 19C, taken along the X, Y1, and Y2 axes, respectively, show an embodiment where the dielectric material 350b (FIG. 15A) is etched to leave a cavity 358 below the source/drain epitaxy 330b.

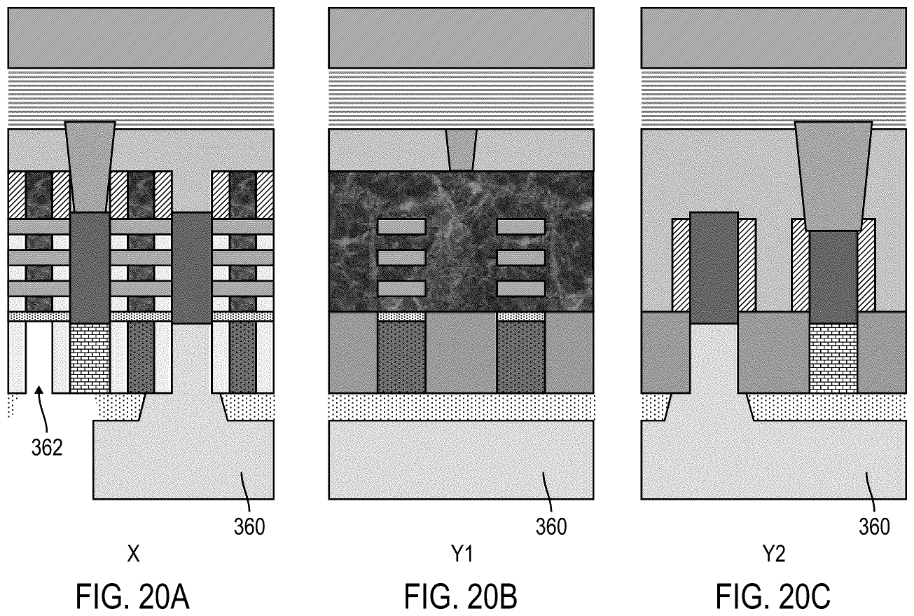

At block 138 in FIG. 1B, the cavity for the backside source/drain contact is filled with an organic planarization layer (OPL). The dielectric material under the gate is removed to form a cavity under the gate for a backside gate contact. FIGS. 20A, 20B, 20C, taken along the X, Y1, and Y2 axes, respectively, show an embodiment where the cavity is filed with the OPL 360. A cavity 362 is etched in the dielectric layer under the gate to allow selective formation of the backside contacts for the source/drain and gate so there is no contact therebetween. In certain embodiments after opening 358 is formed, as shown in FIG. 19A, B, C, a metal fill and CMP process may be performed to complete the source/drain side contact before OPL step shown in FIG. 20. In this way backside source/drain contact and gate contacts are formed by separate metallization process.

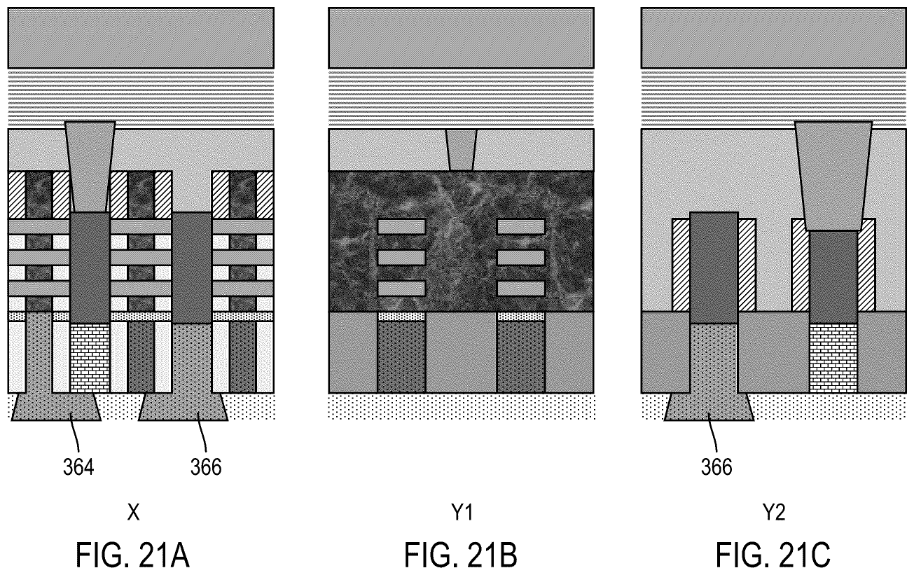

At block 140 in FIG. 1B, the backside metal contacts with copper are formed under backside gate contact and backside source/drain contact. FIGS. 21A, 21B, 21C, taken along the X, Y1, and Y2 axes, respectively, show an embodiment where metallization is used to form the backside gate contact 364. After forming the metalized backside gate contact 364 in the cavity 362, the OPL 360 layer is removed through etching. Metallization is then used to form the backside source/drain contact 366. In this way, the backside source/drain contact 366 is isolated from the backside source/drain contact 364 by the dielectric spacers and the BILD layer. The fill metals for the backside contacts 364, 366 may include, but are not limited to, W, Co, Ru and/or Al, which can be deposited using a process such as CVD, ALD, PVD, sputtering, plating, evaporation, ion beam deposition, electron beam deposition, laser assisted deposition, chemical solution deposition, etc. The overburden is then removed using a process such as chemical mechanical polishing.

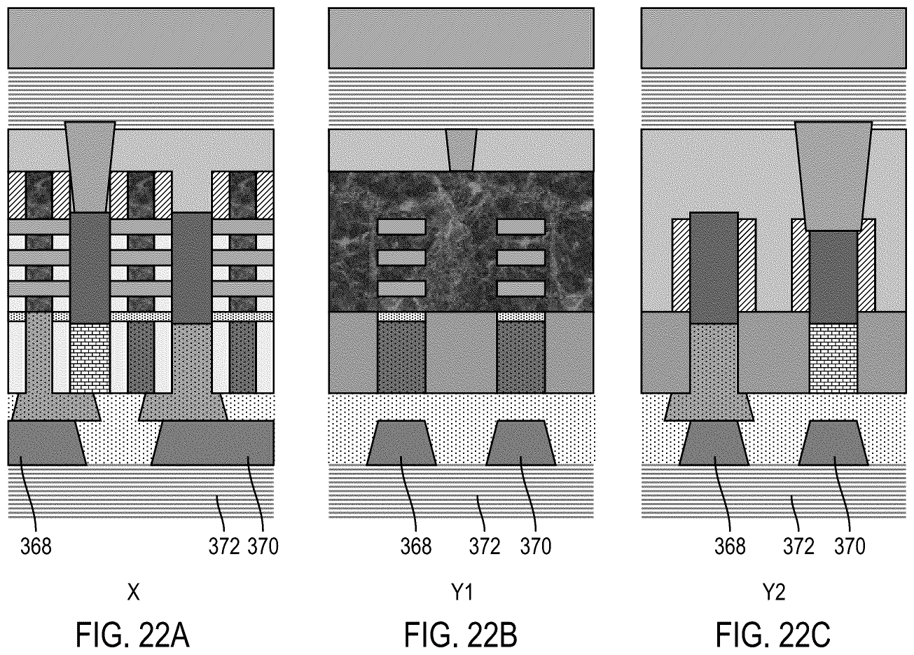

At block 142 in FIG. 1B, backside metal contacts are formed with copper under the backside gate contact and backside source/drain contact. FIGS. 22A, 22B, 22C, taken along the X, Y1, and Y2 axes, respectively, show an embodiment where the backside metals 368, 370 are formed to contact the backside contacts 364, 366, respectively. The backside metals 368, 370 may comprise copper. A backside interconnect is further formed 372 through which the backside metals 368, 370 may contact a bonding or pad connection.

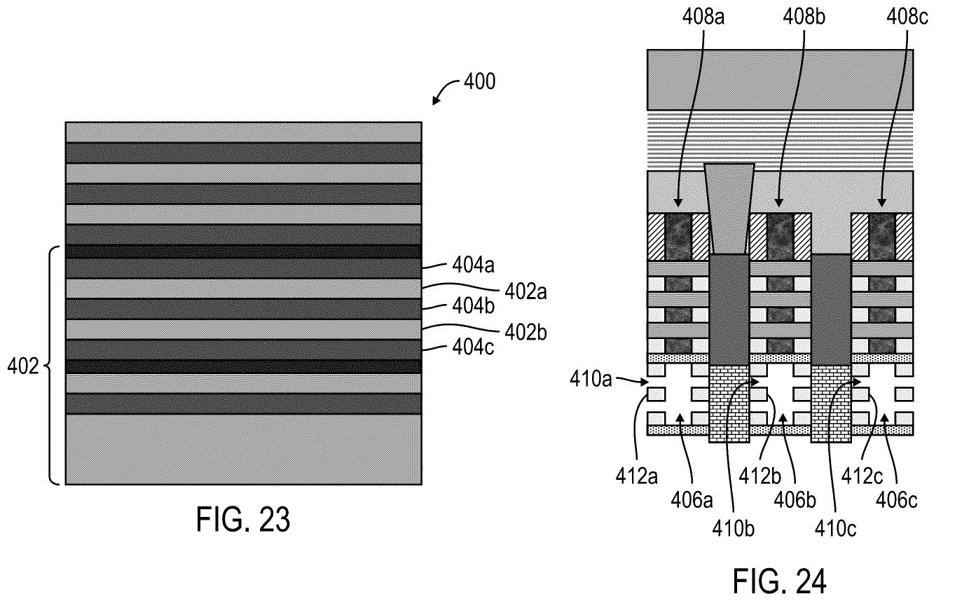

FIG. 23 illustrates an alternative embodiment of the nanosheet stack 400 having additional silicon 402 and sacrificial layers. Additional semiconductor layers 402a, 402b and sacrificial layers 404a, 404b, 404c, which may comprise SiGe30, are added to extend the nanosheet stack 400 over the length of the nanosheet stack 300 in FIG. 3.

FIG. 24 shows an alternative embodiment of the resulting device from the operation performed at step 130 in FIG. 1B of etching the SiGe material to form a cavity 406 under the gates 408a, 408b, 408c. In the alternative embodiment, the etching forms indentations 410a, 410b, 410 in the spacers 412a, 412b, 412c to allow a cross-tab cavity for the dielectric material.

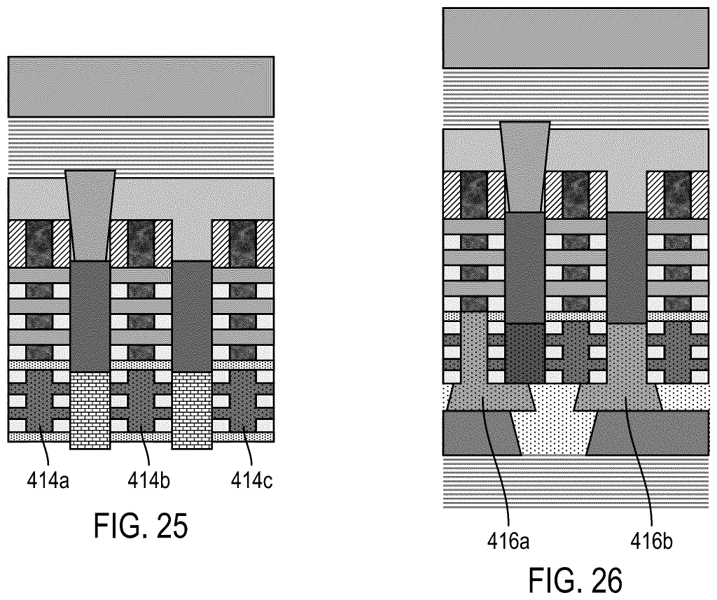

FIG. 25 shows an alternative embodiment of the resulting device from the operation performed at step 132 in FIG. 1b to deposit the dielectric material 414a, 414b, 414c in the cavity and indentation to form a cross-tab region of dielectric material under the gates.

FIG. 26 shows an alternative embodiment of the resulting device from the operation performed at step 138 in FIG. 1B to form the backside gate contact 416a and backside source/drain contact 416b, leaving the dielectric material in the indentations.

In alternative embodiments, there may be an STI liner in the cavity in which the gate dielectric material is formed. The STI liner may be composed of single or multiple layers. Further, the STI liner may be used for self-aligned contacts from backside to frontside.

In alternative embodiments, there may or may not be dielectric material on the sides of the source/drain epitaxy. The dielectric material on the sides of the source/drain epitaxy may be used for confined epitaxy growth or epitaxy separate of the source/drain epitaxies.

In an alternative embodiment, there may not be a bottom dielectric layer (BD( ), and there may be only a single spacer on the backside.

In an alternative embodiment, the spacers extending along the source/drain epitaxies may be comprised of different materials, such as the spacers on the sides of the source/drain epitaxy and the spacers on the side of the backside source/drain contact. Further, the spacers on the sides of the source/drain epitaxy and the spacers on the side of the backside source/drain contact may be formed of the same material.

In alternative embodiments, the source/drain epitaxy may be formed with cavities of different sizes from the top or backside.

In alternative embodiments, a contact may be included on the top of both the source/drain epitaxies. The source/drain contacts may be recessed or wrap around the source/drain epitaxy and contact the backside source/drain contact.

In an alternative embodiment, there may be dielectric bar structures for separation of the source/drain epitaxies. Such a dielectric bar structure may extend through the STI region. Further, there may be multiple dielectric bar structures for separation of the source/drain epitaxies.

In an alternative embodiment, there may be a selective etch for self-alighted contact wrap around of the backside source/drain contact.

The method and structure described herein are used in the manufacture of integrated circuits. The resulting integrated circuit chips can be distributed by the fabricator in raw wafer form (i.e., a single wafer with multiple unpackaged chips), bare die, or packaged form. In the latter case, the chip is placed in a single-chip package (e.g., a plastic carrier with leads attached to a motherboard or other higher-level carrier) or in a multi-chip package (e.g., a ceramic carrier with surface interconnects and/or or buried connections). In either case, the chip is then integrated with other chips, discrete circuit elements, and/or other signal processing devices as part of either (a) an intermediate product, such as a motherboard, or (b) an end product. The end product can be any product that contains integrated circuit chips, ranging from toys and other simple applications to advanced computer products with a display, keyboard or other input device, and a central processor.

The terminology used herein is for the purpose of describing particular embodiments only and is not intended to be limiting of the invention. As used herein, the singular forms “a”, “an” and “the” include the plural forms as well, unless the context clearly indicates otherwise. It is further understood that the terms “comprises” and/or “comprising” when used in this specification specify the presence of particular features, integers, steps, operations, elements and/or components, but the presence or addition one or more other features, integers, steps, operations, elements, components and/or groups thereof. “Optional” means that the event or circumstance described below may or may not occur and that the description includes instances where the event occurs and instances where it does not occur.

Approximate formulations, as used in the specification and claims herein, may be used to modify any quantitative representation that is permissible may vary without leading to a change in the basic function to which it relates. Accordingly, a value modified by one or more of the terms “approximately,” “approximately,” and “substantially” is not limited to the precise value specified. In at least some cases, the approximate formulation may correspond to the accuracy of an instrument used to measure the value. Here and throughout the specification and claims, range boundaries may be combined and/or interchanged; such areas are identified and include all sub-areas therein, unless the context or language indicates otherwise. The term “approximately” applied to a specific value of a range refers to both values and, unless otherwise dependent on the accuracy of the measurement instrument, can mean +/−10% of the declared value(s).

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting.

The description of the present disclosure has been presented for purposes of illustration and description, but is not intended to be exhaustive or limited to the disclosure in the form disclosed. Many modifications and variations will be apparent to those of ordinary skill in the art, and structure or logical changes may be made without departing from the scope and spirit of the disclosure. In particular, elements of the embodiments described hereinafter may be combined with elements of different embodiments. The embodiment was chosen and described in order to best explain the principles of the disclosure and the practical application, and to enable others of ordinary skill in the art to understand the disclosure for various embodiments with various modifications as are suited to the particular use contemplated

What is claimed is:

1. A semiconductor device, comprising:
a source/drain epitaxy;
a first dielectric cap formed under the source/drain epitaxy on a backside of the semiconductor device;
a gate;
a second dielectric cap formed under the gate; and
a spacer separating the first dielectric cap and the source/drain epitaxy from the second dielectric cap and the gate.

2. The semiconductor device of claim 1, further comprising:
gate spacers extended below the gate towards a substrate; and
a source/drain contact from the backside and self-aligned by the gate spacers.

3. The semiconductor device of claim 1, wherein the first dielectric cap and the second dielectric cap are formed from different dielectric materials.

4. The semiconductor device of claim 1, wherein the source/drain epitaxy comprises a first source/drain epitaxy, wherein the gate comprises a first gate, and wherein the spacer comprises a first spacer, further comprising:
a backside gate connector formed under a second gate; and
a second spacer separating the backside gate connector and the second gate from the first dielectric cap and the first source/drain epitaxy.

5. The semiconductor device of claim 1, wherein the source/drain epitaxy comprises a first source/drain epitaxy, and wherein the spacer comprises a first spacer, further comprising:
a backside source/drain connector formed under a second source/drain epitaxy; and
a second spacer separating the backside source/drain connector and the second source/drain epitaxy from the second dielectric cap and the gate.

6. The semiconductor device of claim 1, wherein the spacer comprises a first spacer, further comprising:
a second spacer separating the second dielectric cap from the first dielectric cap; and
additional spacers between nanosheets, wherein the first spacer, the second spacer, and the additional spacers have a same width.

7. The semiconductor device of claim 1, wherein the spacer comprises a first spacer, further comprising:
a second spacer separating the second dielectric cap from the first dielectric cap; and
additional spacers between nanosheets, wherein the first spacer, the second spacer, and the additional spacers are formed of a same material.

8. The semiconductor device of claim 1, further comprising:
a bottom dielectric isolation layer under the gate, wherein the second dielectric cap is formed under the bottom dielectric isolation layer.

9. The semiconductor device of claim 1, wherein the second dielectric cap comprises a body portion under the gate and at least one flange extending outward from a body portion, wherein one of the at least one flange extends toward the first dielectric cap, wherein the at least one flange is surrounded by portions of the spacer.

10. A semiconductor device, comprising:
a source/drain epitaxy;
a first gate;
a second gate, wherein the source/drain epitaxy is located between the first and the second gates;
a backside source/drain connector formed under the source/drain epitaxy on a backside of the semiconductor device; and
spacers on both sides of the backside source/drain connector to separate the backside source/drain connector from first and the second gates.

11. The semiconductor device of claim 10, further comprising:
a third gate; and
a backside gate connector formed under the third gate.

12. The semiconductor device of claim 11, wherein the source/drain epitaxy comprises a first source/drain epitaxy, wherein the spacers comprise a first spacer and a second spacer, further comprising:
a second source/drain epitaxy; and
a third spacer between the backside gate connector and the second source/drain epitaxy to separate the backside gate connector and the second source/drain epitaxy.

13. The semiconductor device of claim 12, further comprising:
a dielectric cap under the first gate, wherein the first spacer further separates the dielectric cap from the backside source/drain connector.

14. A method of fabricating a semiconductor device, comprising:
etching a stack of nanosheet layers to form a first gate, a second gate, and a third gate, with a first trench between the first gate and the second gate and a second trench between the second gate and the third gate, wherein the first, second and third gates include SiGe layers and silicon layers;
etching the SiGe layers to form indentations in the first gate, the second gate, and the third gate;
forming spacer material in the indentations in the first gate, the second gate, and the third gate;
forming a first source/drain epitaxy in the first trench, wherein the spacer material in the indentations in the first and the second gates separate the first source/drain epitaxy from the first and the second gates; and
forming a second source/drain epitaxy in the second trench, wherein the spacer material in the indentations in the second and the third gates separate the second source/drain epitaxy from the second and the third gates.

15. The method of claim 14, further comprising:
etching from a bottom of the first source/drain epitaxy to form a first cavity between the spacer material of the first and the second gates;
etching from a bottom of the second source/drain epitaxy to form a second cavity between the spacer material of the second and the third gates; and
forming a first dielectric material in the first and the second cavities.

16. The method of claim 15, further comprising:
etching backside cavities in bottom regions of the first gate, the second gate, and the third gate between the spacer material formed in the indentations in the first gate, the second gate, and the third gate;
forming indentations in the spacer material opening into the backside cavities below the first gate, the second gate, and the third gate; and
forming a second dielectric material in the backside cavities and the indentations in the spacer material.

17. The method of claim 15, further comprising:
etching backside cavities in bottom regions of the first gate, the second gate, and the third gate between the spacer material formed in the indentations in the first gate, the second gate, and the third gate; and
forming a second dielectric material in the backside cavities.

18. The method of claim 17, wherein the first dielectric material is different from the second dielectric material to allow selective etching of the first dielectric material and the second dielectric material to selectively form a backside source/drain contact and a backside gate contact, respectively.

19. The method of claim 17, further comprising:
etching a third cavity in the first dielectric material under the second source/drain epitaxy;
etching a fourth cavity in the second dielectric material under the first gate; and
forming an organic planarization layer in the third cavity.

20. The method of claim 19, further comprising:
forming a first backside metal contact in the fourth cavity; and
removing the organic planarization layer to form a fifth cavity in response to forming the first backside metal contact; and
forming a second backside metal contact in the fifth cavity.
